(19) United States
(12) Patent Application Publication
(10) Pub. No.: US 2026/0090010 A1
(43) Pub. Date: Mar. 26, 2026

(54) SEMICONDUCTOR DEVICE AND POWER CONVERSION DEVICE

(71) Applicant: Mitsubishi Electric Corporation, Tokyo (JP)

(72) Inventor: Hiroki TACHIBANA, Tokyo (JP)

(73) Assignee: Mitsubishi Electric Corporation, Tokyo (JP)

(21) Appl. No.: 19/187,143

(22) Filed: Apr. 23, 2025

(30) Foreign Application Priority Data
Sep. 20, 2024 (JP) 2024-163881

(51) Int. Cl. H10D 30/66; H01L 23/00; H01L 23/29; H01L 23/31; H10D 62/10

(52) U.S. Cl. CPC H10D 30/665; H10D 62/102; H10W 42/00; H10W 74/137; H10W 74/43

(57) ABSTRACT

A semiconductor device includes: a semiconductor substrate on which a device is provided; a metal wire provided on an upper surface of the semiconductor substrate and connected to the device; a passivation film which is an inorganic insulating film covering a corner portion of the metal wire and includes an opening provided on an upper surface of the metal wire; and an organic protective film covering the metal wire exposed from the opening.

### BACKGROUND OF THE INVENTION

### Field

The present disclosure relates to a semiconductor device and a power conversion device.

### Background

In a semiconductor device, a passivation film covers a metal wire provided on the semiconductor substrate (see, for example, Patent Literature 1).
Patent Literature 1: JP H4-348523 A

### SUMMARY

Since it has been customary that a passivation film is formed so as to uniformly cover a metal wire, the passivation film has been likely to be destroyed by influence of thermal stress. In addition, since an organic protective film is provided on the passivation film, when a metal wire is exposed from the passivation film, the metal wire forms an interface with the organic protective film. However, there has been a problem in which the organic protective film reacts and deteriorates at the interface between the organic protective film and the corner portion of the metal wire where the electric field is concentrated, reducing reliability such as moisture resistance and durability.

The present disclosure has been made to solve the above-mentioned problems, and an object of the present disclosure is to obtain a semiconductor device and a power conversion device capable of improving reliability.

### Solution to Problem

A semiconductor device according to the present disclosure includes: a semiconductor substrate on which a device is provided; a metal wire provided on an upper surface of the semiconductor substrate and connected to the device; a passivation film which is an inorganic insulating film covering a corner portion of the metal wire and includes an opening provided on an upper surface of the metal wire; and an organic protective film covering the metal wire exposed from the opening.

### Advantageous Effects of Invention

In the present disclosure, an opening is provided in the passivation film on the upper surface of the metal wire. This can alleviate the thermal stress that the passivation film receives from the metal wire and can prevent the occurrence of cracks in the passivation film. The passivation film covers the corner portion of the metal wire. This allows the electric field concentration portions of the metal wire not to be in contact with the organic protective film, preventing deterioration of the organic protective film at the interface between the organic protective film and the metal wire. This can prevent peeling of the organic protective film to improve moisture resistance. As a result, reliability such as durability can be improved.

### BRIEF DESCRIPTION OF DRAWINGS

FIG. 1 is a plan view showing a semiconductor device according to a first embodiment.

FIG. 2 is a plan view of FIG. 1 with an organic protective film omitted.

FIG. 3 is a cross-sectional view of the outer periphery in the short side direction of the chip taken along line I-II in FIG. 1.

FIG. 4 is a cross-sectional view of a corner portion taken along III-IV in FIG. 1.

FIG. 5 is an enlarged plan view of a part of a modified example of the semiconductor device according to the first embodiment.

FIG. 6 is a plan view showing a semiconductor device according to a second embodiment.

FIG. 7 is a plan view showing a semiconductor device according to a third embodiment.

FIG. 8 is an enlarged plan view of a part of the semiconductor device according to the third embodiment.

FIG. 9 is a plan view showing a semiconductor device according to a fourth embodiment.

FIG. 10 is a cross-sectional view taken along line I-II in FIG. 9.

FIG. 11 is an enlarged plan view of a part of a modified example of the semiconductor device according to the fourth embodiment.

FIG. 12 is a plan view showing a semiconductor device according to a fifth embodiment.

FIG. 13 is a plan view showing a semiconductor device according to a sixth embodiment.

FIG. 14 is an enlarged plan view of a part of a first modified example of the semiconductor device according to the sixth embodiment.

FIG. 15 is an enlarged plan view of a part of a second modified example of the semiconductor device according to the sixth embodiment.

FIG. 16 is a plan view showing a semiconductor device according to a seventh embodiment.

FIG. 17 is a cross-sectional view taken along line I-II in FIG. 16.

FIG. 18 is a block diagram illustrating a configuration of an electric power conversion system to which the electric power conversion device according to the eight embodiment is applied.

### DESCRIPTION OF EMBODIMENTS

A semiconductor device and a power conversion device according to the embodiments of the present disclosure will be described with reference to the drawings. The same components will be denoted by the same symbols, and the repeated description thereof may be omitted.

### First Embodiment

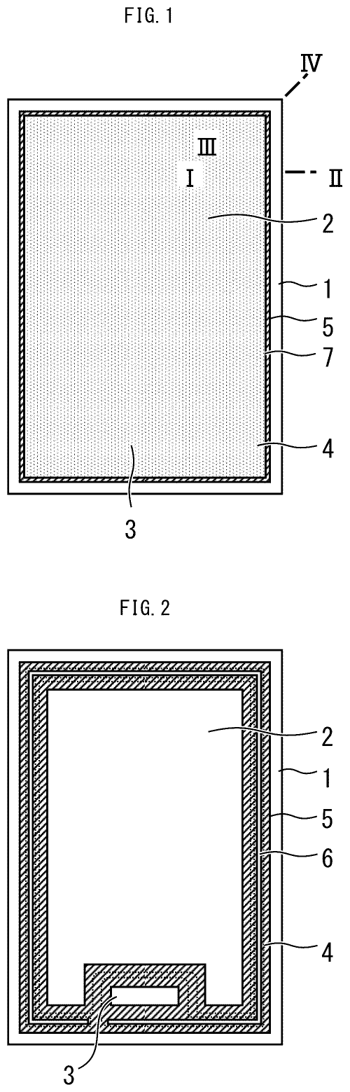

FIG. 1 is a plan view showing a semiconductor device according to a first embodiment. FIG. 2 is a plan view of FIG. 1 with an organic protective film omitted. A source electrode 2 is provided in the central portion of the upper surface of a semiconductor substrate 1. A gate pad 3 and a gate wire 4 connected thereto are provided in the outer peripheral region around the source electrode 2 on the upper surface of the semiconductor substrate 1. The source electrode 2, the gate pad 3, and the gate wire 4 are metal wires.

A passivation film 5 is provided on the semiconductor substrate 1, the outer periphery of the source electrode 2, the outer periphery of the gate pad 3, and the gate wire 4. The passivation film 5 is, for example, a nitride film. The passivation film 5 covers the metal wires in a terminal portion to protect a termination region. An opening 6 is provided in the passivation film 5 on the outermost periphery of the gate pad 3 and on the gate wire 4.

An organic protective film 7 is provided on the semiconductor substrate 1, the passivation film 5, and the gate wire 4. The organic protective film 7 covers the region where the passivation film 5 is not present to protect the semiconductor substrate 1. The passivation film 5 and the organic protective film 7 provide waterproofing and anti-oxidation effects. The central portion of the gate pad 3 and the central portion of the source electrode 2 are not covered with the passivation film 5 and are exposed in order to make electrical contact such as wire bonding.

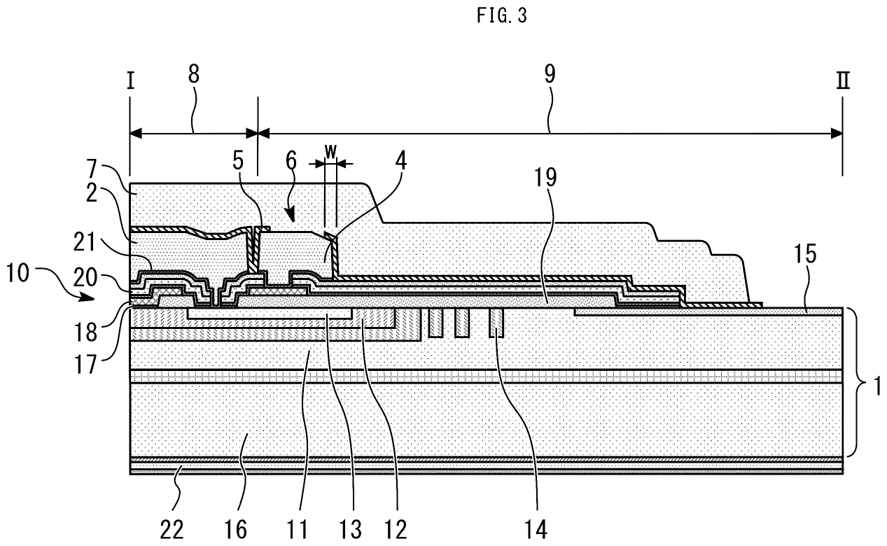

FIG. 3 is a cross-sectional view of the outer periphery in the short side direction of the chip taken along line I-II in FIG. 1. In the semiconductor substrate 1, an outer peripheral region 9 is provided so as to surround an active region 8 through which a main current flows. A MOSFET (Metal Oxide Semiconductor Field Effect Transistor) is provided as a device 10 in the active region 8. Other than this, a Schottky diode, an IGBT (Insulated Gate Bipolar Transistor), or the like may be provided as the device 10.

In the semiconductor substrate 1, a P-type layer 12 is provided on an N⁻-type drift layer 11. An N-type source region 13 is provided on a part of the P-type layer 12. A P-type withstand voltage holding structure 14 is provided in the N⁻-type drift layer 11 in the outer peripheral region 9 of the semiconductor substrate 1. An N-type channel stop region 15 is provided in the outermost periphery on the N⁻-type type drift layer 11. An N⁺-type drain layer 16 is provided under an N⁻-type type drift layer 11.

In the active region 8 of the semiconductor substrate 1, a gate electrode 18 is formed on the P-type layer 12 via a gate insulating film 17. An insulating oxide film 19 is provided on the outer peripheral region 9 of the semiconductor substrate 1, and covers the P-type withstand voltage holding structure 14 and a part of the N-type channel stop region 15 to protect the semiconductor substrate 1. An insulating oxide film 20 is provided so as to cover the semiconductor substrate 1, the gate electrode 18, and the insulating oxide film 19. The insulating oxide films 19 and 20 are, for example, silicon oxide films.

In the active region 8, the source electrode 2 is provided on the insulating oxide film 20 via a barrier metal 21. The source electrode 2 is connected to an N-type source region 13 through an opening in the insulating oxide film 20. In the outer peripheral region 9, the gate wire 4 is provided on the insulating oxide film 20 via a barrier metal 21. The gate wire 4 passes through an opening in the insulating oxide film 20 and is connected to the lead-out portion of the gate electrode 18 that is led out on the insulating oxide film 19. Therefore, the gate wire 4 and the source electrode 2 provided on the upper surface of the semiconductor substrate 1 are electrically connected to the device 10. In addition, a drain electrode 22 is provided on the lower surface of the semiconductor substrate 1 and is connected to the N⁺-type drain layer 16.

The passivation film 5 covers the semiconductor substrate 1, the gate wire 4, and the source electrode 2. In the upper surface of the gate wire 4, an opening 6 is provided in the passivation film 5 along the gate wire 4. The passivation film 5 covers the side surface of the gate wire 4 and the outer edge portion of the upper surface of the gate wire 4. A plurality of openings 6 may be provided on the gate wire 4. The width of the opening 6 is smaller than the width of the gate wire 4. The organic protective film 7 covers and protects the gate wire 4 exposed from the opening 6.

The passivation film 5 has a thickness of 0.5 μm to 2 μm. The passivation film 5 is formed, for example, by a CVD method. A resist film is applied onto the passivation film 5, and a photomask is placed over the resist film to form a laminate. The laminate is then exposed to light and etched to form an opening 6 in the passivation film 5.

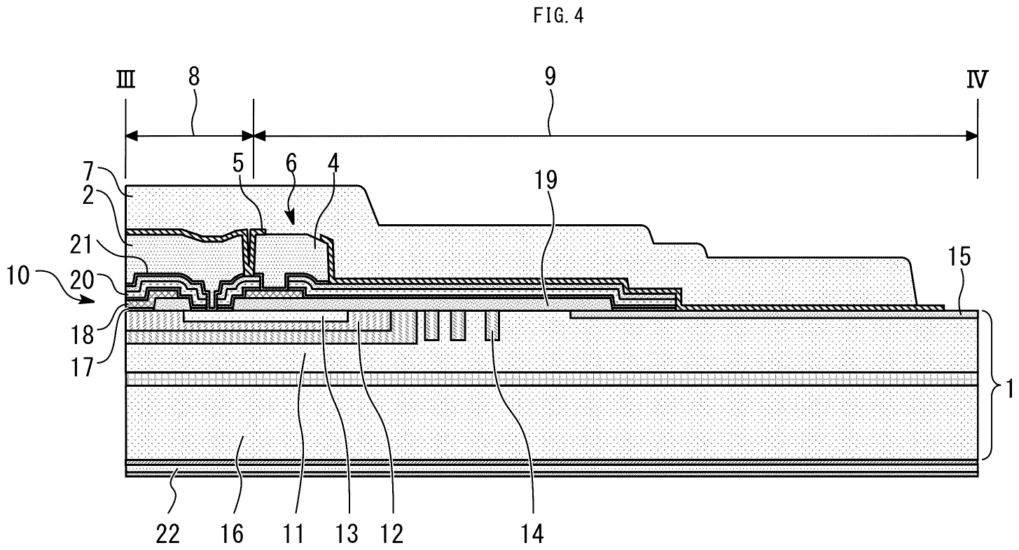

FIG. 4 is a cross-sectional view of a corner portion taken along III-IV in FIG. 1. The structure of the corner portion of the semiconductor substrate 1 is basically the same as that in FIG. 3, but the region between the outer end of the insulating oxide film 20 and the end of the semiconductor substrate 1 is wider than that in FIG. 3. The corner portion is therefore susceptible to the influence of thermal stress in the passivation film 5 and the adhesive strength of the organic protective film 7.

As the area of the continuous passivation film 5 increases, the passivation film 5 receives larger thermal stress from the gate wire 4. Therefore, in this embodiment, an opening 6 is provided in the passivation film 5 on the upper surface of the gate wire 4. This can alleviate the thermal stress that the passivation film 5 receives from the gate wire 4 in environmental change or in operation, and can prevent the occurrence of cracks in the passivation film 5. In addition, the shape of the organic protective film 7 that fits into the opening 6 provides an anchor effect, improving the adhesion of the organic protective film 7.

An electric field is concentrated in the corner portions between the upper surface and side surface of the gate wire 4. The passivation film 5 thus covers the corner portions of the gate wire 4. This allows the electric field concentration portions of the gate wire 4 not to be in contact with the organic protective film 7, preventing deterioration of the organic protective film 7 at the interface between the organic protective film 7 and the gate wire 4. This can prevent peeling of the organic protective film 7 to improve moisture resistance. As a result, reliability such as durability can be improved.

In addition, it is preferable that the width w of the narrowest part of the passivation film 5 covering the outer edge portion of the upper surface of the gate wire 4 be larger than the thickness of the passivation film 5. This can prevent the opening 6 from reaching the corner of the gate wire 4, preventing exposure of the corner portion of the gate wire 4.

The gate wire 4 is provided in the outer peripheral region 9 along the outer periphery of the semiconductor substrate 1 in a plan view. Therefore, the opening 6 provided on the upper surface of the gate wire 4 is provided in the outer peripheral region 9 along the outer periphery of the semiconductor substrate 1 in a plan view. This allows the thermal stress received by the passivation film 5 to be alleviated over a wide range. The opening 6 is provided only on the upper surface of the gate wire 4. This reduces the contact area between the semiconductor substrate 1 and the organic protective film 7, thereby preventing deterioration of the contact interface.

The passivation film 5 is, for example, a nitride film, but any inorganic insulating film may be used. The passivation film 5 made of a silicon nitride film can ensure moisture resistance, reduce the influence of the electric field, and reduce a decrease in the interface strength with the organic protective film 7.

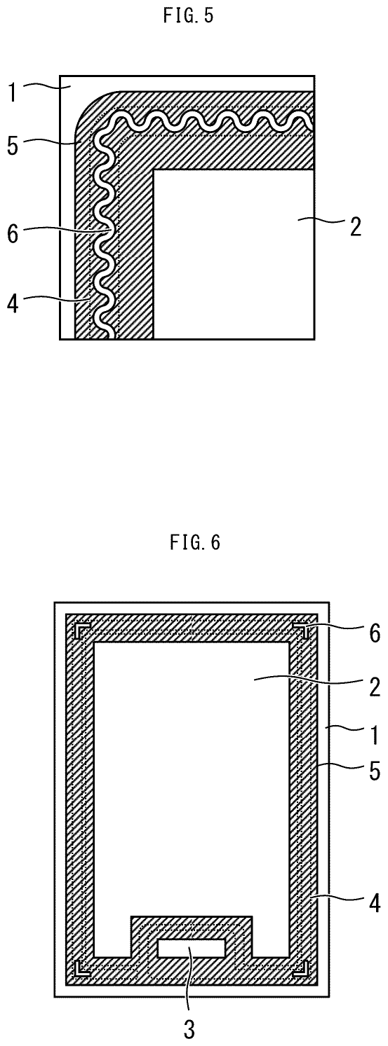

FIG. 5 is an enlarged plan view of a part of a modified example of the semiconductor device according to the first embodiment. The opening 6 of the passivation film 5 are wavy in a plan view. Therefore, the planar shape of the opening 6 has no acute angles smaller than 90 degrees. This can eliminate stress concentration parts and further reduce the load on the passivation film 5, further improving reliability.

### Second Embodiment

FIG. 6 is a plan view showing a semiconductor device according to a second embodiment. The openings 6 are provided in the passivation film 5 on the gate wire 4 only in the corner portions of the semiconductor substrate 1. Each opening 6 is provided in the corner portion where stress is likely to concentrate, allowing for preventing the occurrence of cracks in the passivation film 5. In addition, since the gate wire 4 other than the corner portions is covered with the passivation film 5, the area in which the passivation film 5 covers and protects the gate wire 4 can be expanded. The other configurations and effects are the same as those in the first embodiment.

### Third Embodiment

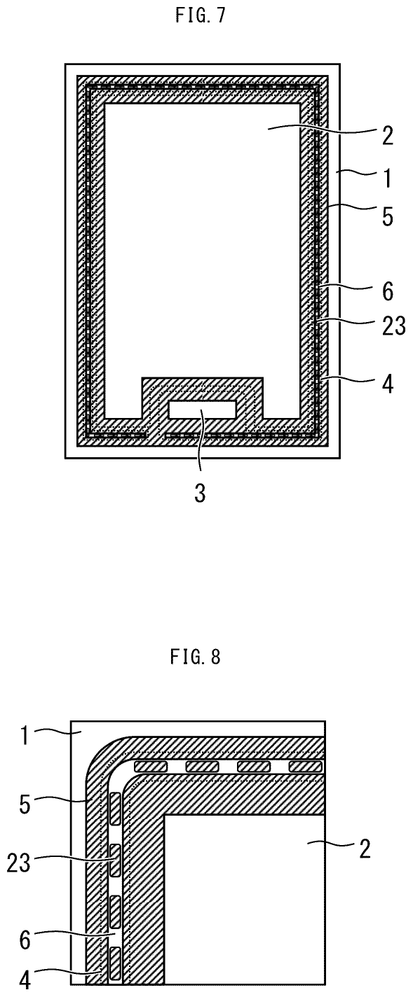

FIG. 7 is a plan view showing a semiconductor device according to a third embodiment. FIG. 8 is an enlarged plan view of a part of the semiconductor device according to the third embodiment. An opening 6 is provided in the passivation film 5 along the gate wire 4. There are a plurality of remaining regions 23 of the passivation film 5 within the opening 6.

Providing a plurality of remaining regions 23 makes it possible to expand the area in which the passivation film 5 covers and protects the gate wire 4. In addition, the organic protective film 7, which fits into the opening 6 where there are the plurality of remaining regions 23, provides an anchor effect, further improving the adhesion of the organic protective film 7. The other configurations and effects are the same as those in the first embodiment.

### Fourth Embodiment

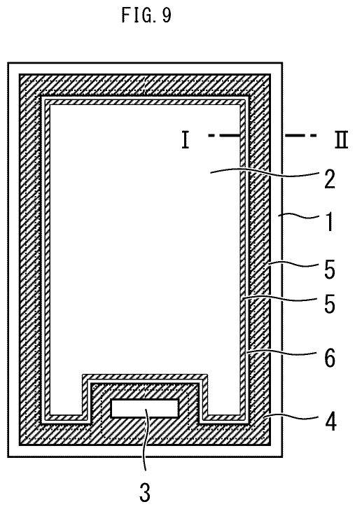

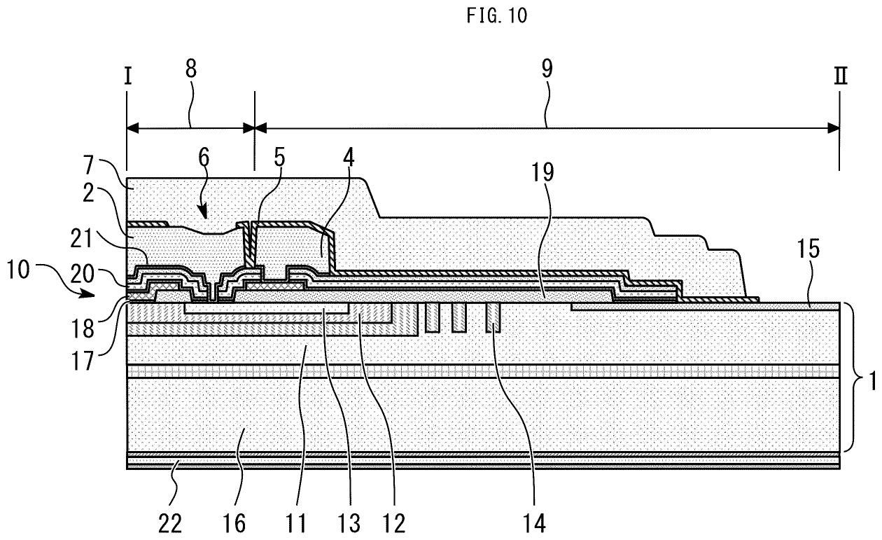

FIG. 9 is a plan view showing a semiconductor device according to a fourth embodiment. FIG. 10 is a cross-sectional view taken along line I-II in FIG. 9. This embodiment differs from the first embodiment in the location of the opening 6 provided. The passivation film 5 covers the outer periphery of the source electrode 2. An opening 6 is provided on the outer periphery of the source electrode 2 along the outer periphery of the source electrode 2 in a plan view. This can alleviate the thermal stress that the passivation film 5 receives from the source electrode 2 in environmental change or in operation, and can prevent the occurrence of cracks in the passivation film 5. In addition, the shape of the organic protective film 7 that fits into the opening 6 provides an anchor effect, improving the adhesion of the organic protective film 7.

In addition, an electric field is concentrated in the corner portion between the upper surface and side surface of the source electrode 2. For this reason, the passivation film 5 covers the corner portion of the source electrode 2. As a result, the electric field concentration portion of the source electrode 2 is not in contact with the organic protective film 7, so that deterioration of the organic protective film 7 can be prevented at the interface between the organic protective film 7 and the corner portion where the electric field concentrates. This can prevent peeling of the organic protective film 7 to improve moisture resistance. As a result, reliability such as durability can be improved.

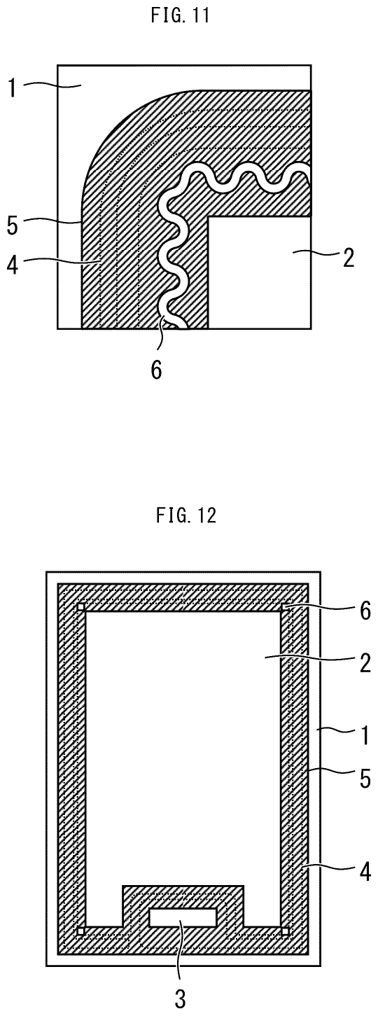

FIG. 11 is an enlarged plan view of a part of a modified example of the semiconductor device according to the fourth embodiment. The opening 6 of the passivation film 5 are wavy in a plan view. Therefore, the planar shape of the opening 6 has no acute angles smaller than 90 degrees. This can eliminate stress concentration parts and further reduce the load on the passivation film 5, further improving reliability.

### Fifth Embodiment

FIG. 12 is a plan view showing a semiconductor device according to a fifth embodiment. Only in the corner portions of the source electrode 2, openings 6 are provided in the passivation film 5 that covers the outer periphery of the source electrode 2. Each opening 6 is provided in the corner portion where stress is likely to concentrate, allowing for preventing the occurrence of cracks in the passivation film 5. In addition, since the source electrode 2 other than the corner portions is covered with the passivation film 5, the area can be expanded in which the passivation film 5 covers and protects the outer periphery of the source electrode 2. The other configurations and effects are the same as those of the fourth embodiment.

### Sixth Embodiment

FIG. 13 is a plan view showing a semiconductor device according to a sixth embodiment. An opening 6 is provided in the passivation film 5 in the outer periphery of the source electrode 2. There are a plurality of remaining regions 23 of the passivation film 5 within the opening 6.

Providing a plurality of remaining regions 23 can expand the area in which the passivation film 5 covers and protects the outer periphery of the source electrode 2. In addition, the organic protective film 7, which fits into the opening 6 where there are the plurality of remaining regions 23, provides an anchor effect, further improving the adhesion of the organic protective film 7. The other configurations and effects are the same as those of the fourth embodiment.

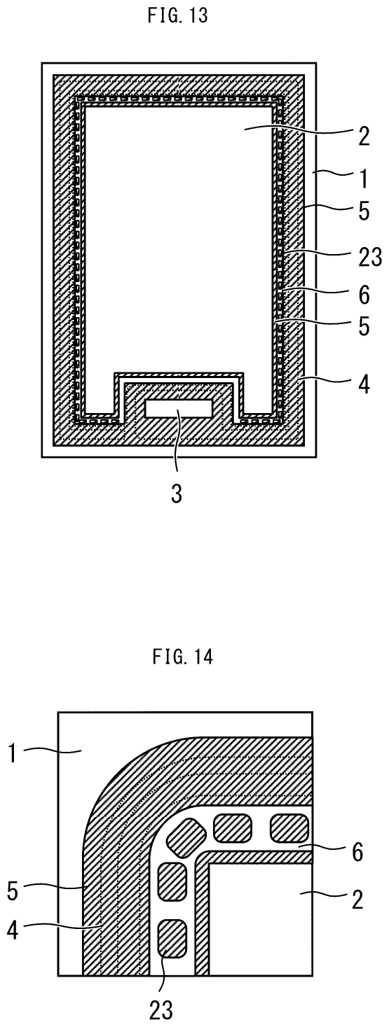

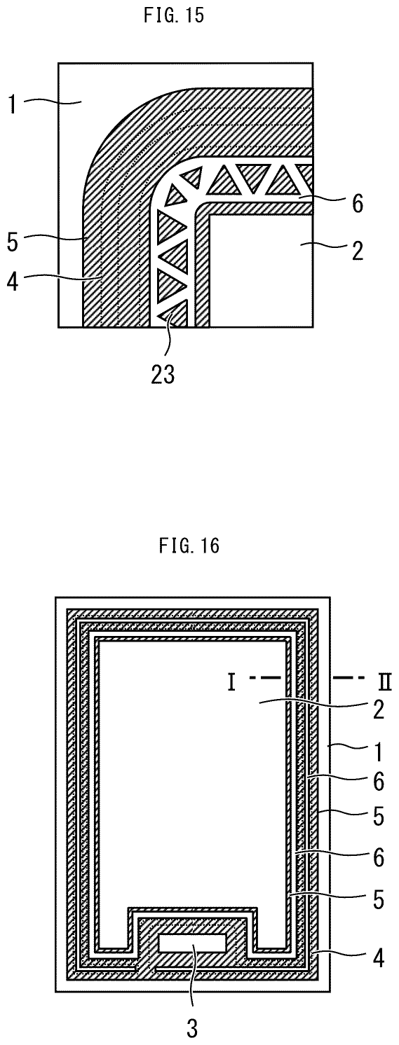

FIG. 14 is an enlarged plan view of a part of a first modified example of the semiconductor device according to the sixth embodiment. Each remaining region 23 is rectangular. FIG. 15 is an enlarged plan view of a part of a second modified example of the semiconductor device according to the sixth embodiment. Each remaining region 23 is triangular. However, if there is a sharp point in the remaining region 23, stress will be concentrated in that part. It is therefore preferable to round all corners of the remaining region 23. In other words, the remaining region 23 is preferably a polygon or a circle without acute angles.

### Seventh Embodiment

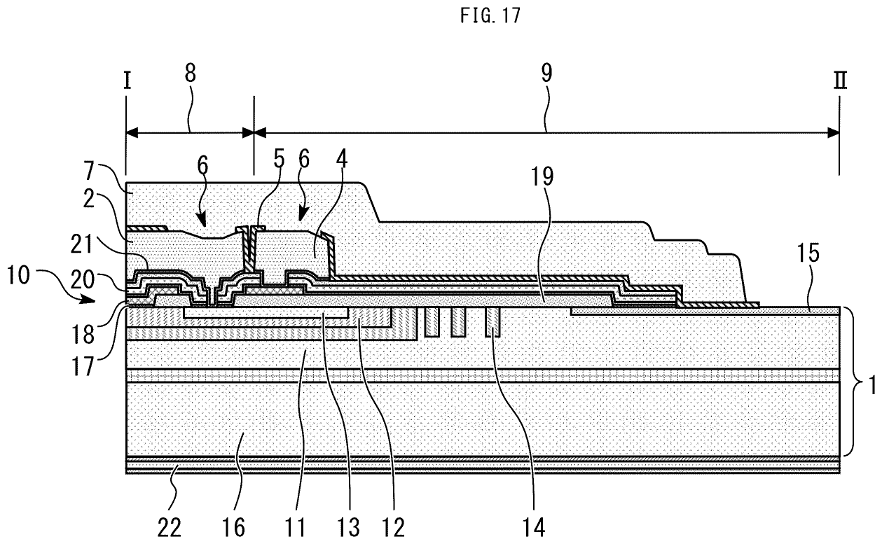

FIG. 16 is a plan view showing a semiconductor device according to a seventh embodiment. FIG. 17 is a cross-sectional view taken along line I-II in FIG. 16. The openings 6 are provided on both the upper surface of the gate wire 4 and the outer periphery of the source electrode 2. The anchor effect of both further improves the adhesion of the organic protective film 7, and the large openings 6 further alleviate the thermal stress that the passivation film 5 receives, thereby preventing the occurrence of cracks in the passivation film 5. Note that the openings 6 of both may have the same shape, or may be a combination of different shapes.

The semiconductor substrate 1 is not limited to being made of silicon, and may be made of a wide band gap semiconductor that has a larger band gap than silicon. The wide band gap semiconductor is, for example, silicon carbide, a gallium nitride-based material, or diamond. A semiconductor device made of such a wide band gap semiconductor has a high voltage resistance and a high allowable current density, and it can therefore be miniaturized. Use of this miniaturized semiconductor device also allows the semiconductor module incorporating this semiconductor device to be miniaturized and highly integrated. In addition, the semiconductor device having high heat resistance allows the heat dissipation fins of the heat sink to be made smaller, and allows the water-cooled portion to be air-cooled, enabling the semiconductor module to be further miniaturized. In addition, the semiconductor device has low power loss and high efficiency, so that the semiconductor module can be highly efficient.

### Eight Embodiment

In this embodiment, the semiconductor devices according to the first to seven embodiments described above are applied to an electric power conversion device. Although the present disclosure is not limited to a specific electric power conversion device, a case where the present disclosure is applied to a three-phase inverter will be described below as eight embodiment.

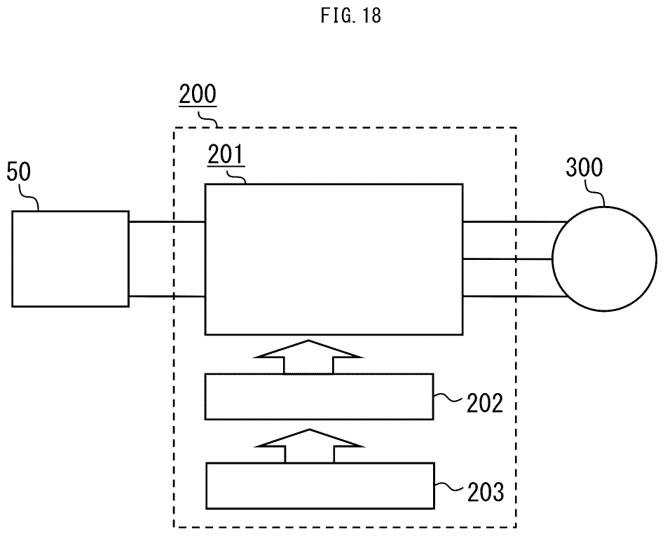

FIG. 18 is a block diagram illustrating a configuration of an electric power conversion system to which the electric power conversion device according to the eight embodiment is applied. This electric power conversion system includes a power supply 50, an electric power conversion device 200, and a load 300. The power supply 50 is a DC power supply and supplies DC power to the electric power conversion device 200. The power supply 50 can be composed of various components. For example, the power supply 50 can be composed of a DC system, a solar cell, or a storage battery, or may be composed of a rectifier or an AC/DC converter, which is connected to an AC system. Alternatively, the power supply 50 may be composed of a DC/DC converter that convers DC power output from a DC system to predetermined power.

The electric power conversion device 200 is a three-phase inverter connected to a node between the power supply 50 and the load 300, converts DC power supplied from the power supply 50 into AC power, and supplies the AC power to the load 300. The electric power conversion device 200 includes a main conversion circuit 201 that converts DC power to AC power for output, a drive circuit 202 that outputs drive signals to drive each switching device of the main conversion circuit 201, and a control circuit 203 that outputs control signals to the drive circuit 202 to control the drive circuit 202.

The load 300 is a three-phase electric motor that is driven by AC power supplied from the electric power conversion device 200. The load 300 is not limited to a specific application. The load is used as an electric motor mounted on various electric devices, such as an electric motor for, for example, a hybrid vehicle, an electric vehicle, a railroad vehicle, an elevator, or an air-conditioner.

The electric power conversion device 200 will be described in detail below. The main conversion circuit 201 includes a switching device and a reflux diode (not illustrated). When the switching device is switched, the main conversion circuit 201 converts DC power supplied from the power supply 50 into AC power, and supplies the AC power to the load 300. The main conversion circuit 201 may have various types of specific circuit configurations. The main conversion circuit 201 according to this embodiment is a two-level three-phase full-bridge circuit, which can be composed of six switching devices and six reflux diodes connected in antiparallel with the respective switching devices. Each switching device and each reflux diode of the main conversion circuit 201 are composed of a semiconductor device 202 corresponding to any one of the first to seven embodiments described above. Every two switching devices of the six switching devices are connected in series and constitute a vertical arm. Each vertical arm constitutes each phase (U-phase, V-phase, W-phase) of the full-bridge circuit. Output terminals of each vertical arm, i.e., three output terminals of the main conversion circuit 201, are connected to the load 300.

Further, the main conversion circuit 201 includes a drive circuit (not illustrated) that drives each switching device. The drive circuit may be incorporated in the semiconductor device 202. Another drive circuit different from the semiconductor device 202 may be provided.

The drive circuit 202 generates a drive signal for driving each switching device of the main conversion circuit 201, and supplies the generated drive signal to a control electrode of each switching device of the main conversion circuit 201. Specifically, the drive circuit outputs, to the control electrode of each switching device, a drive signal for turning on each switching device and a drive signal for turning off each switching device, according to the control signal output from the control circuit 203, which is described later. When the ON-state of each switching device is maintained, the drive signal is a voltage signal (ON signal) having a voltage equal to or higher than a threshold voltage of the switching device. When the OFF-state of each switching device is maintained, the drive signal is a voltage signal (OFF signal) having a voltage equal to or lower than the threshold voltage of the switching device.

The control circuit 203 controls each switching device of the main conversion circuit 201 so as to supply a desired power to the load 300. Specifically, the control circuit 203 calculates a period (ON period), in which each switching device of the main conversion circuit 201 is in the ON state, based on the power to be supplied to the load 300. For example, the main conversion circuit 201 can be controlled by a PWM control for modulating the ON period of each switching device depending on the voltage to be output. Further, the control circuit 203 outputs a control command (control signal) to the drive circuit 202 included in the main conversion circuit 201 so that the ON signal is output to each switching device to be turned on and an OFF signal is output to each switching device to be turned off at each point. The drive circuit 202 outputs the ON signal or OFF signal, as the drive signal, to the control electrode of each switching device according to the control signal.

In the electric power conversion device according to this embodiment, since a semiconductor device according to any of first to seventh embodiments is applied as the switching device of the main conversion circuit 201, reliability can be improved.

While this embodiment illustrates an example in which the present disclosure is applied to a two-level three-phase inverter, the present disclosure is not limited to this and can be applied to various electric power conversion devices. While this embodiment illustrates a two-level electric power conversion device, the present disclosure can also be applied to a three-level or multi-level electric power conversion device. When power is supplied to a single-phase load, the present disclosure may be applied to a single-phase inverter. The present disclosure can also be applied to a DC/DC converter or an AC/DC converter when power is supplied to a DC load or the like.

Further, in the electric power conversion device to which the present disclosure is applied, the above-mentioned load is not limited to an electric motor. For example, the load may also be used as a power supply device for an electric discharge machine, a laser beam machine, an induction heating cooker, or a non-contact device power feeding system. More alternatively, the electric power conversion device may be used as a power conditioner for a photovoltaic power generating system, an electricity storage system, or the like.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### Supplementary Note 1

A semiconductor device comprising:
a semiconductor substrate on which a device is provided;
a metal wire provided on an upper surface of the semiconductor substrate and connected to the device;
a passivation film which is an inorganic insulating film covering a corner portion of the metal wire and includes an opening provided on an upper surface of the metal wire; and
an organic protective film covering the metal wire exposed from the opening.

### Supplementary Note 2

The semiconductor device according to Supplementary Note 1, wherein the metal wire includes a gate wire provided on an outer peripheral region of the semiconductor substrate, and
the opening is provided on an upper surface of the gate wire.

### Supplementary Note 3

The semiconductor device according to Supplementary Note 2, wherein the opening is provided only in a corner portion of the semiconductor substrate in a plan view.

### Supplementary Note 4

The semiconductor device according to Supplementary Note 1, wherein the metal wire includes a source electrode,
the passivation film covers an outer periphery of the source electrode, and
the opening is provided on the outer periphery of the source electrode.

### Supplementary Note 5

The semiconductor device according to Supplementary Note 4, wherein the opening is provided only in a corner portion of the source electrode in a plan view.

### Supplementary Note 6

The semiconductor device according to Supplementary Note 1, wherein the metal wire includes a gate wire and a source electrode,
the passivation film covers the gate wire and outer periphery of the source electrode, and
the opening is provided on both an upper surface of the gate wire and the outer periphery of the source electrode.

### Supplementary Note 7

The semiconductor device according to any one of Supplementary Notes 1 to 6, wherein a plurality of remaining regions of the passivation film are present within the opening.

### Supplementary Note 8

The semiconductor device according to Supplementary Note 7, wherein the remaining region is a circle or a polygon without acute angles.

### supplementary Note 9

The semiconductor device according to any one of Supplementary Notes 1 to 8, wherein a width of the narrowest part of the passivation film covering an outer edge portion of the upper surface of the metal wire is larger than a thickness of the passivation film.

### Supplementary Note 10

The semiconductor device according to any one of Supplementary Notes 1 to 9, wherein a planar shape of the opening has no acute angles smaller than 90 degrees.

### Supplementary Note 11

The semiconductor device according to any one of Supplementary Notes 1 to 10, wherein the opening is provided only on an upper surface of the metal wire.

### Supplementary Note 12

The semiconductor device according to any one of Supplementary Notes 1 to 11, wherein the passivation film is a silicon nitride film.

### Supplementary Note 13

The semiconductor device according to any one of Supplementary Notes 1 to 12, wherein the semiconductor substrate is made of a wide-band-gap semiconductor.

### Supplementary Note 14

A power conversion device comprising:
a main conversion circuit including the semiconductor device according to any one of Supplementary Notes 1 to 13, converting input power and outputting converted power;
a drive circuit outputting a drive signal for driving the semiconductor device to the semiconductor device, and
a control circuit outputting a control signal for controlling the drive circuit to the drive circuit.

### REFERENCE SIGNS LIST

1 semiconductor substrate; 2 source electrode (metal wire); 4 gate wire (metal wire); 5 passivation film; 6 opening; 7 organic protective film; 10 device; 23 remaining region; 200 electric power conversion device; 201 main conversion circuit; 202 drive circuit; 203 control circuit

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-163881, filed on Sep. 20, 2024 including specification, claims, drawings and summary, on which the convention priority of the present application is based, is incorporated herein by reference in its entirety.

1. A semiconductor device comprising:
a semiconductor substrate on which a device is provided;
a metal wire provided on an upper surface of the semiconductor substrate and connected to the device;
a passivation film which is an inorganic insulating film covering a corner portion of the metal wire and includes an opening provided on an upper surface of the metal wire; and
an organic protective film covering the metal wire exposed from the opening.

2. The semiconductor device according to claim 1, wherein the metal wire includes a gate wire provided on an outer peripheral region of the semiconductor substrate, and
the opening is provided on an upper surface of the gate wire.

3. The semiconductor device according to claim 2, wherein the opening is provided only in a corner portion of the semiconductor substrate in a plan view.

4. The semiconductor device according to claim 1, wherein the metal wire includes a source electrode,
the passivation film covers an outer periphery of the source electrode, and
the opening is provided on the outer periphery of the source electrode.

5. The semiconductor device according to claim 4, wherein the opening is provided only in a corner portion of the source electrode in a plan view.

6. The semiconductor device according to claim 1, wherein the metal wire includes a gate wire and a source electrode,
the passivation film covers the gate wire and outer periphery of the source electrode, and
the opening is provided on both an upper surface of the gate wire and the outer periphery of the source electrode.

7. The semiconductor device according to claim 1, wherein a plurality of remaining regions of the passivation film are present within the opening.

8. The semiconductor device according to claim 7, wherein the remaining region is a circle or a polygon without acute angles.

9. The semiconductor device according to claim 1, wherein a width of the narrowest part of the passivation film covering an outer edge portion of the upper surface of the metal wire is larger than a thickness of the passivation film.

10. The semiconductor device according to claim 1, wherein a planar shape of the opening has no acute angles smaller than 90 degrees.

11. The semiconductor device according to claim 1, wherein the opening is provided only on an upper surface of the metal wire.

12. The semiconductor device according to claim 1, wherein the passivation film is a silicon nitride film.

13. The semiconductor device according to claim 1, wherein the semiconductor substrate is made of a wide-band-gap semiconductor.

14. A power conversion device comprising:
a main conversion circuit including the semiconductor device according to claim 1, converting input power and outputting converted power;
a drive circuit outputting a drive signal for driving the semiconductor device to the semiconductor device, and
a control circuit outputting a control signal for controlling the drive circuit to the drive circuit.
